(19) United States
(12) Patent Application Publication
(10) Pub. No.: US 2019/0088195 A1
(43) Pub. Date: Mar. 21, 2019

(54) MURA CORRECTION FOR AN LED DISPLAY

(71) Applicant: SYNAPTICS INCORPORATED, San Jose, CA (US)

(72) Inventors: Kasra KHAZENI, San Jose, CA (US); Damien BERGET, Sunnyvale, CA (US)

(21) Appl. No.: 15/706,189

(22) Filed: Sep. 15, 2017

(51) Int. Cl. G09G 3/32

(52) U.S. Cl. CPC G09G 3/32; H01L 27/323

(57) ABSTRACT

An example processing system for driving a display having light-emitting diode (LED) sub-pixels is described. The processing system comprises a memory that stores a first plurality of values for a first LED sub-pixel of the LED sub-pixels and a processing circuit. The processing circuit is configured to: receive image data for the display, the image data comprising a first input digital code for the first LED sub-pixel; and generate a first output digital code using a non-linear function having an argument and a plurality of constant parameters, where the processing circuit is configured to set the argument to the first input digital code and the plurality of constant parameters to the first plurality of values. The processing system further comprises a display driver, coupled to the display and the processing circuit, comprising a first digital-to-analog converter (DAC) configured to control intensity of emitted light from the first LED sub-pixel in response to the first output digital code.

### BACKGROUND

### Field of the Disclosure

Embodiments of disclosure generally relate to displays and, more particularly, mura correction for a light emitting diode (LED) display.

### Description of the Related Art

In a light-emitting diode (LED) display, variations of thin-film transistors (TFTs) per sub-pixel, and variations of the sub-pixels themselves, cause visually detectable non-uniformities on the displayed images. Manufacturers rely on an externally measured luminosity of each sub-pixel as a function of grey level to program their display drivers to equalize the luminance of all sub-pixels to compensate for non-uniformities. Present equalization techniques may fail to completely compensate for the non-uniformity depending on the presence of parasitic resistances in the sub-pixels.

### SUMMARY

In an embodiment, a processing system for driving a display having light-emitting diode (LED) sub-pixels is described. The processing system comprises a memory that stores a first plurality of values for a first LED sub-pixel of the LED sub-pixels and a processing circuit coupled to the memory. The processing circuit is configured to: receive image data for the display, the image data comprising a first input digital code for the first LED sub-pixel; and generate a first output digital code using a non-linear function having an argument and a plurality of constant parameters, where the processing circuit is configured to set the argument to the first input digital code and the plurality of constant parameters to the first plurality of values. The processing system further comprises a display driver, coupled to the display and the processing circuit, comprising a first digital-to-analog converter (DAC) configured to control intensity of emitted light from the first LED sub-pixel in response to the first output digital code.

In another embodiment, an input device comprises a display having light-emitting diode (LED) sub-pixels and a processing system coupled to the display. The processing system comprises a memory that stores a first plurality of values for a first LED sub-pixel of the LED sub-pixels and a processing circuit coupled to the memory. The processing circuit is configured to: receive image data for the display, the image data comprising a first input digital code for the first LED sub-pixel; and generate a first output digital code using a non-linear function having an argument and a plurality of constant parameters, where the processing circuit is configured to set the argument to the first input digital code and the plurality of constant parameters to the first plurality of values. The processing system further comprises a display driver, coupled to the display and the processing circuit, comprising a first digital-to-analog converter (DAC) configured to control intensity of emitted light from the first LED sub-pixel in response to the first output digital code.

In another embodiment, a method of driving a display, the display comprising light-emitting diode (LED) sub-pixels is described. The method comprises receiving image data for the display, the image data comprising a first input digital code for a first LED sub-pixel of the LED sub-pixels; obtaining a first plurality of values for the first LED sub-pixel from a memory; generating, using a processing circuit coupled to the memory, a first output digital code using a non-linear function having an argument and a plurality of constant parameters, where the processing circuit is configured to set the argument to the first input digital code and the plurality of constant parameters to the first plurality of values; and supplying the first output digital code to a first digital-to-analog converter (DAC) configured to control intensity of emitted light from the first LED sub-pixel in response to the first output digital code.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a block diagram of an exemplary input device in accordance with embodiments of the disclosure.

FIG. 2 is a block diagram illustrating example details of an input device according to some embodiments.

FIG. 3 is a schematic diagram depicting an light-emitting diode (LED) sub-pixel and associated drive circuitry according to an embodiment.

FIG. 4 is a graph depicting input code versus output code for an LED sub-pixel.

FIG. 5 is a flow diagram depicting a method of driving an LED sub-pixel of a display according to an embodiment.

To facilitate understanding, identical reference numerals have been used, where possible, to designate identical elements that are common to the figures. It is contemplated that elements disclosed in one embodiment may be beneficially utilized on other embodiments without specific recitation. The drawings referred to here should not be understood as being drawn to scale unless specifically noted. Also, the drawings are often simplified and details or components omitted for clarity of presentation and explanation. The drawings and discussion serve to explain principles discussed below, where like designations denote like elements.

### DETAILED DESCRIPTION

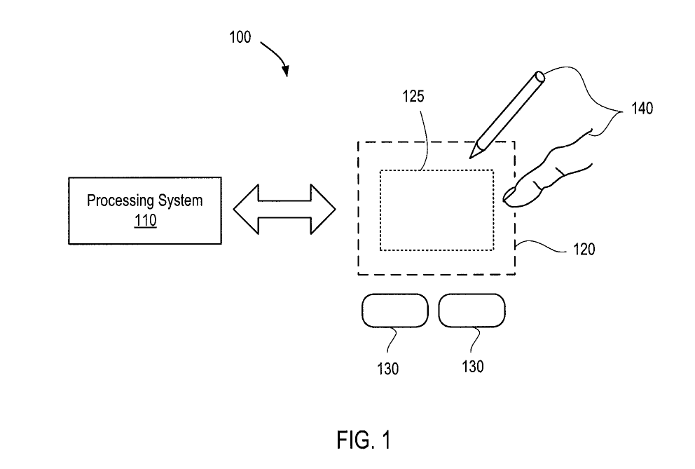

FIG. 1 is a block diagram of an exemplary input device 100 in accordance with embodiments of the disclosure. The input device 100 may be configured to provide input to an electronic system (not shown). As used in this document, the term “electronic system” (or “electronic device”) broadly refers to any system capable of electronically processing information. Some non-limiting examples of electronic systems include personal computers of all sizes and shapes, such as desktop computers, laptop computers, netbook computers, tablets, web browsers, e-book readers, and personal digital assistants (PDAs). Additional example electronic systems include composite input devices, such as physical keyboards that include input device 100 and separate joysticks or key switches. Further example electronic systems include peripherals such as data input devices (including remote controls and mice), and data output devices (including display screens and printers). Other examples include remote terminals, kiosks, and video game machines (e.g., video game consoles, portable gaming devices, and the like). Other examples include communication devices (including cellular phones, such as smart phones), and media devices (including recorders, editors, and players such as televisions, set-top boxes, music players, digital photo frames, and digital cameras). Additionally, the electronic system could be a host or a slave to the input device.

The input device 100 can be implemented as a physical part of the electronic system, or can be physically separate from the electronic system. As appropriate, the input device 100 may communicate with parts of the electronic system using any one or more of the following: buses, networks, and other wired or wireless interconnections. Examples include I²C, SPI, PS/2, Universal Serial Bus (USB), Bluetooth, RF, and IRDA.

In FIG. 1, the input device 100 is shown as a proximity sensor device (also often referred to as a “touchpad” or a “touch sensor device”) configured to sense input provided by one or more input objects 140 in a sensing region 120. Example input objects include fingers and styli, as shown in FIG. 1.

The sensing region 120 encompasses any space above, around, in and/or near the input device 100 in which the input device 100 is able to detect user input (e.g., user input provided by one or more input objects 140). The sizes, shapes, and locations of particular sensing regions may vary widely from embodiment to embodiment. In some embodiments, the sensing region 120 extends from a surface of the input device 100 in one or more directions into space until signal-to-noise ratios prevent sufficiently accurate object detection. The distance to which this sensing region 120 extends in a particular direction, in various embodiments, may be on the order of less than a millimeter, millimeters, centimeters, or more, and may vary significantly with the type of sensing technology used and the accuracy desired. Thus, some embodiments sense input that comprises no contact with any surfaces of the input device 100, contact with an input surface (e.g. a touch surface) of the input device 100, contact with an input surface of the input device 100 coupled with some amount of applied force or pressure, and/or a combination thereof. In various embodiments, input surfaces may be provided by surfaces of casings within which the sensor electrodes reside, by face sheets applied over the sensor electrodes or any casings, etc. In some embodiments, the sensing region 120 has a rectangular shape when projected onto an input surface of the input device 100.

The input device 100 may utilize any combination of sensor components and sensing technologies to detect user input in the sensing region 120. The input device 100 comprises one or more sensing elements for detecting user input. As several non-limiting examples, the input device 100 may use capacitive, elastive, resistive, inductive, magnetic, acoustic, ultrasonic, and/or optical techniques. In an embodiment, the processing system 110 operates the sensing elements to implement touch nodes 125. A touch node 125 is an area in sensing region 120 in which the processing system 110 can detect a change in capacitance due to the presence of input objects 140.

Some implementations are configured to provide images that span one, two, three, or higher dimensional spaces. Some implementations are configured to provide projections of input along particular axes or planes.

In some capacitive implementations of the input device 100, voltage or current is applied to create an electric field. Nearby input objects cause changes in the electric field, and produce detectable changes in capacitive coupling that may be detected as changes in voltage, modulated current, or the like.

Some capacitive implementations utilize arrays or other regular or irregular patterns of capacitive sensing elements to create electric fields. In some capacitive implementations, separate sensing elements may be ohmically shorted together to form larger sensor electrodes. Some capacitive implementations utilize resistive sheets, which may be uniformly resistive. Some sensing elements may be integrated or combined with the display device (e.g. diode anode or cathode) or they may be separate (e.g. on another electrically isolated layer) from the display device electrodes.

Some capacitive implementations utilize “self capacitance” (or “absolute capacitance”) sensing methods based on changes in the capacitive coupling between sensor electrodes and an input object. In various embodiments, an input object near the sensor electrodes alters the electric field near the sensor electrodes, thus changing the measured capacitive coupling. In one implementation, an absolute capacitance sensing method operates by modulating sensor electrodes with respect to a reference voltage (e.g. system ground), and by detecting the capacitive coupling between the sensor electrodes and input objects.

A processing system 110 is shown as part of the input device 100. The processing system 110 is configured to operate the hardware of the input device 100 to detect input in the sensing region 120. The processing system 110 comprises parts of or all of one or more integrated circuits (ICs) and/or other circuitry components. For example, a processing system for a mutual capacitance sensor device may comprise transmitter circuitry configured to transmit signals with transmitter sensor electrodes, and/or receiver circuitry configured to receive signals with receiver sensor electrodes (e.g. the receiver electrodes may be segmented cathode electrodes of the display). In some embodiments, the processing system 110 also comprises electronically-readable instructions, such as firmware code, software code, and/or the like. In some embodiments, components composing the processing system 110 are located together, such as near sensing element(s) of the input device 100. In other embodiments, components of processing system 110 are physically separate with one or more components close to sensing element(s) of input device 100, and one or more components elsewhere. For example, the input device 100 may be a peripheral coupled to a desktop computer, and the processing system 110 may comprise software configured to run on a central processing unit of the desktop computer and one or more ICs (perhaps with associated firmware) separate from the central processing unit. As another example, the input device 100 may be physically integrated in a phone, and the processing system 110 may comprise circuits and firmware that are part of a main processor of the phone. In some embodiments, the processing system 110 is dedicated to implementing the input device 100. In other embodiments, the processing system 110 also performs other functions, such as operating display screens, driving haptic actuators, etc.

The processing system 110 may be implemented as a set of modules that handle different functions of the processing system 110. Each module may comprise circuitry that is a part of the processing system 110, firmware, software, or a combination thereof. In various embodiments, different combinations of modules may be used. Example modules include hardware operation modules for operating hardware such as sensor electrodes and display screens, data processing modules for processing data such as sensor signals and positional information, and reporting modules for reporting information. Further example modules include sensor operation modules configured to operate sensing element(s) to detect input, identification modules configured to identify gestures such as mode changing gestures, and mode changing modules for changing operation modes.

In some embodiments, the processing system 110 responds to user input (or lack of user input) in the sensing region 120 directly by causing one or more actions. Example actions include changing operation modes, as well as GUI actions such as cursor movement, selection, menu navigation, and other functions. In some embodiments, the processing system 110 provides information about the input (or lack of input) to some part of the electronic system (e.g. to a central processing system of the electronic system that is separate from the processing system 110, if such a separate central processing system exists). In some embodiments, some part of the electronic system processes information received from the processing system 110 to act on user input, such as to facilitate a full range of actions, including mode changing actions and GUI actions.

For example, in some embodiments, the processing system 110 operates the sensing element(s) of the input device 100 to produce electrical signals indicative of input (or lack of input) in the sensing region 120. The processing system 110 may perform any appropriate amount of processing on the electrical signals in producing the information provided to the electronic system. For example, the processing system 110 may digitize analog electrical signals obtained from the sensor electrodes. As another example, the processing system 110 may perform filtering or other signal conditioning. As yet another example, the processing system 110 may subtract or otherwise account for a baseline, such that the information reflects a difference between the electrical signals and the baseline. As yet further examples, the processing system 110 may determine positional information, recognize inputs as commands, recognize handwriting, and the like.

“Positional information” as used herein broadly encompasses absolute position, relative position, velocity, acceleration, and other types of spatial information. Exemplary “zero-dimensional” positional information includes near/far or contact/no contact information. Exemplary “one-dimensional” positional information includes positions along an axis. Exemplary “two-dimensional” positional information includes motions in a plane. Exemplary “three-dimensional” positional information includes instantaneous or average velocities in space. Further examples include other representations of spatial information. Historical data regarding one or more types of positional information may also be determined and/or stored, including, for example, historical data that tracks position, motion, or instantaneous velocity over time.

In some embodiments, the input device 100 is implemented with additional input components that are operated by the processing system 110 or by some other processing system. These additional input components may provide redundant functionality for input in the sensing region 120, or some other functionality. FIG. 1 shows buttons 130 near the sensing region 120 that can be used to facilitate selection of items using the input device 100. Other types of additional input components include sliders, balls, wheels, switches, and the like. Conversely, in some embodiments, the input device 100 may be implemented with no other input components.

In some embodiments, the input device 100 comprises a touch screen interface, and the sensing region 120 overlaps at least part of an active area of a display screen. For example, the input device 100 may comprise substantially transparent sensor electrodes overlaying the display screen and provide a touch screen interface for the associated electronic system. The display screen may be any type of dynamic display capable of displaying a visual interface to a user, and may include any type of light emitting diode (LED), organic LED (OLED), cathode ray tube (CRT), liquid crystal display (LCD), plasma, electroluminescence (EL), or other display technology. The input device 100 and the display screen may share physical elements. For example, some embodiments may utilize some of the same electrical components for displaying and sensing. As another example, the display screen may be operated in part or in total by the processing system 110. In one embodiment, OLED display driver circuitry and touch sensing circuitry may be combined into a single Integrated Circuit (TDDI).

It should be understood that while many embodiments of the disclosure are described in the context of a fully functioning apparatus, the mechanisms of the present disclosure are capable of being distributed as a program product (e.g., software) in a variety of forms. For example, the mechanisms of the present disclosure may be implemented and distributed as a software program on information bearing media that are readable by electronic processors (e.g., non-transitory computer-readable and/or recordable/writable information bearing media readable by the processing system 110). Additionally, the embodiments of the present disclosure apply equally regardless of the particular type of medium used to carry out the distribution. Examples of non-transitory, electronically readable media include various discs, memory sticks, memory cards, memory modules, and the like. Electronically readable media may be based on flash, optical, magnetic, holographic, or any other storage technology.

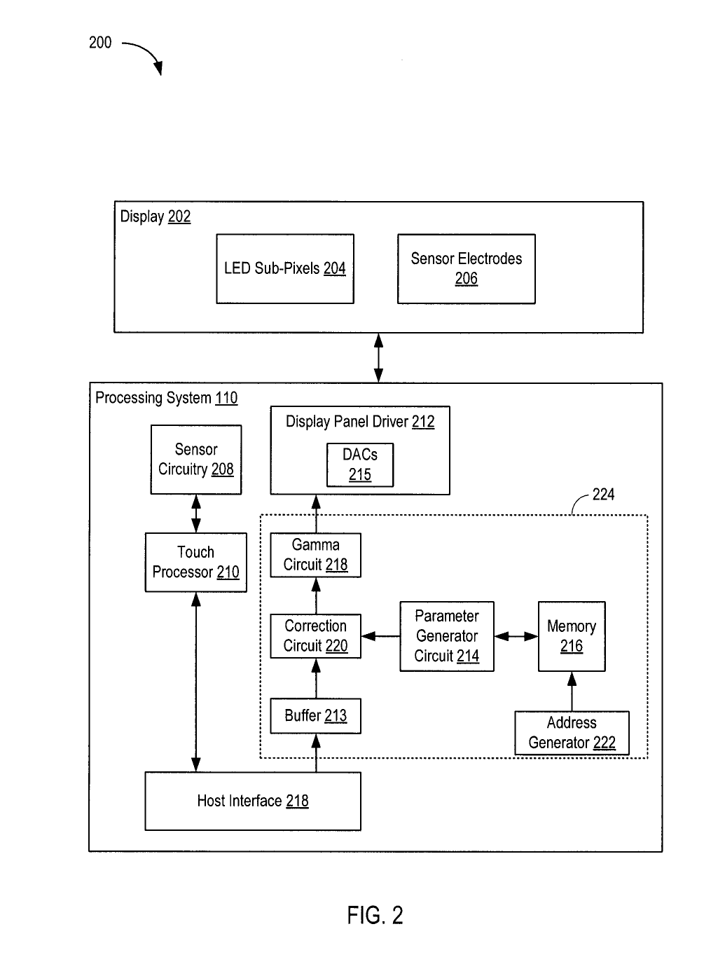

FIG. 2 is a block diagram illustrating example details of the input device 100 according to some embodiments. As shown in FIG. 2, the processing system 110 is coupled to a display 202. In an embodiment, the processing system 110 comprises a single integrated controller, such as an application specific integrated circuit (ASIC). In another embodiment, the processing system 110 can include a plurality of integrated circuits. The processing system 110 can be coupled to other integrated circuits, such as a host processor (not shown).

The display 202 includes a plurality of light-emitting diode (LED) sub-pixels 204, such as OLED sub-pixels or the like. The display 202 can also include sensor electrodes 206. The sensor electrodes 206 implement the touch nodes 125 used for capacitive input sensing. In an embodiment, the sensor electrodes 206 are dedicated electrodes disposed on one or more substrates of the display 202. In another embodiment, the sensor electrodes 206 are also electrodes used by the LED sub-pixels 204 (e.g., cathode electrodes, anode electrodes, etc.). In another embodiment, the sensor electrodes 206 include both dedicated sensor electrodes and electrodes of the LED sub-pixels 204. In some embodiments, the processing system 110 operates the sensor electrodes 206 using absolute capacitive sensing to obtain capacitive images. In other embodiments, the processing system 110 operates some sensor electrodes 206 as transmitters and other sensor electrodes 206 as receivers and obtains capacitive images using transcapacitive sensing.

The processing system 110 includes sensor circuitry 208, a touch processor 210, a display panel driver 212, processing circuits 224, and a host interface 218. The processing circuits 224 include a buffer 213, a correction circuit 220, a gamma circuit 218, a parameter generator circuit 214, a memory 216, and an address generator 222. The sensor circuitry 208 is coupled to the sensor electrodes 206. The sensor circuitry 208 operates the sensor electrodes 206 to receive resulting signals using either an absolute capacitive or transcapacitive sensing scheme. The sensor circuitry 208 can include charge measurement circuits (e.g., charge integrators, current conveyers, etc.), demodulators, filters, analog-to-digital converter(s), and the like. The sensor circuitry 208 supplies the resulting signals to the touch processor 210. The touch processor 210 determines changes in capacitance, object proximity, object location, object force, or the like by processing the resulting signals. The touch processor 210 can include special purpose processors (e.g., digital signal processor(s)), general purpose processors executing software/firmware, or a combination thereof. The touch processor 210 can further include various support circuitry, including memory, input/output (IO) circuits, and the like.

The buffer 213 stores image data received from the host interface 218. For example, the buffer 213 can be a frame buffer. The stored image data includes digital codes for representing the grey scale value of each of the LED sub-pixels 204. For example, the digital codes can be 8-bit codes representing a grey scale value between 0 and 255. An output of the buffer 213 is coupled to an input of the correction circuit 220. The correction circuit 220 is configured to modify the digital codes stored in the buffer 213 before the digital codes are supplied to the display panel driver 212. As discussed further below, the correction circuit 220 modifies the digital codes of the image data to compensate for variations of the LED sub-pixels 204 that, if uncompensated, would cause detectable non-uniformities in the display images (e.g., mura compensation). The memory 216 stores a set of values for each LED sub-pixel 204 that control the applied compensation. The address generator 222 generates addresses for the memory 216, which outputs the sets of values. The parameter generator 214 generates parameters from the sets of values. The correction circuit 220 includes multipliers, adders, and the like that implement a non-linear function having an argument and a plurality of constant parameters. The buffer 213 supplies the arguments of the function and the parameter generator 214 supplies the values of the constant parameters. The gamma circuit 218 applies a gamma function to the digital codes output by the correction circuit 220. The gamma circuit 218 outputs digital codes to the display panel driver 212.

In an embodiment, the memory 216 stores a compressed representation of the values for each LED sub-pixel 204. This reduces the size of the memory 216. In such an embodiment, the parameter generator circuit 214 includes a decompressor configured to obtain the values for each LED sub-pixel 204 from the compressed data stored in the memory 216.

The display panel driver 212 can include source drivers or both source drivers and gate drivers. In some embodiments, the gate drivers can be part of the display 202 (e.g., a gate-in-panel (GIP) display). The source drivers drive the display 202 to display the image data via the LED sub-pixels 204. The source drivers include digital-to-analog converters (DACs) 215 that covert the digital codes output by the gamma circuit 218 into analog voltages. The gate drivers select lines of the display 202 based on timing control data. The gate drivers select LED sub-pixels 204 through gate switches, and the source drivers can update the selected LED sub-pixels 204 drive current, according to image data.

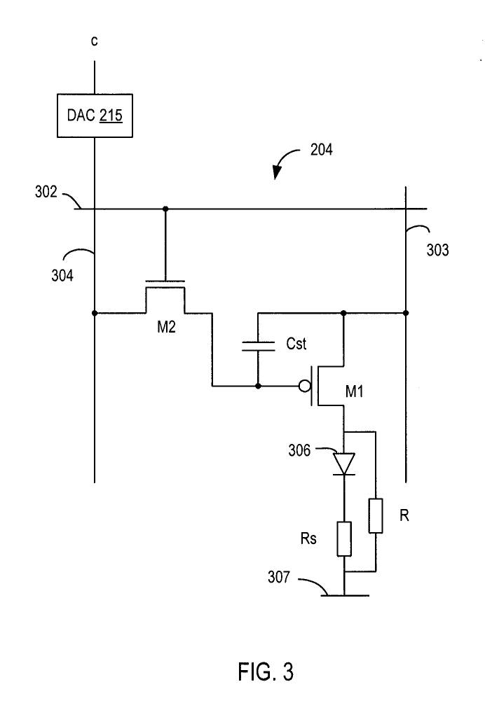

FIG. 3 is a schematic diagram depicting an LED sub-pixel and associated drive circuitry according to an embodiment. While a specific structure of the drive circuitry is shown by way of example, those skilled in the art will appreciate that other driver circuitry structures can be employed and that the techniques for mura compensation described herein are not limited to any particular drive circuitry structure. As shown in the example of FIG. 3, an LED sub-pixel 204 includes an n-channel field effect transistor (FET) M2, a p-channel FET M1, a capacitor Cst, and an LED 306. The FETs M1 and M2 can be TFTs. An anode of the LED 306 is coupled between a drain of the transistor M1 and a cathode electrode 307. The LED sub-pixel 204 can include parasitic resistances Rs and R. The parasitic resistance Rs is coupled between the cathode of the LED 306 and the cathode electrode 307. The parasitic resistance R is coupled between the anode of the LED 306 and the cathode electrode 307.

The source of the transistor M1 is coupled to a supply line 303. The capacitor Cst is coupled between the supply line 303 and the gate of the transistor M1. The gate and source of the transistor M1 are capacitively coupled by way of the capacitor Cst. The drain of the transistor M1 is coupled to the anode of the LED 306. A gate of the transistor M2 is coupled to a gate line 302. A drain of the transistor M2 is coupled to the gate of the transistor M1. A source of the transistor M2 is coupled to a source line 304. The source line 304 is coupled to a DAC 215. The DAC 215 can be formed on the display 202 or be part of the display panel driver 212. The gate line 302 can be coupled to a gate driver (not shown) formed either on the display 202 or as part of the display panel driver 212.

To emit light (when displaying an image), the LED 306 can be forward-biased (and can thus have current flowing through it). To forward-bias the LED 306, the voltage at the gate line 302 can be sufficiently high to turn on the transistor M2. When the transistor M2 is on, the transistor M2 can act substantially as a short-circuit and can cause the voltage at the source line 304 to be substantially mirrored at the gate of the transistor M1 and the voltage stored on Cst. The voltage at the source line 304, and thus the voltage at the gate of the transistor M1, can be sufficiently low relative to the anode supply voltage to turn on the current-controlling transistor M1. When the transistor M1 is on, the transistor M1 can act substantially as current source and can cause the voltage at the anode of the LED 306 to be maintained at a voltage for a controlled current through the LED 306. For the LED 306 to be forward biased, the voltage at the anode must be higher than the voltage at the cathode electrode 307. The configuration of the LED sub-pixel shown in FIG. 3 is merely one example of various types of LED sub-pixels that can be included in an LED display.

The grey scale of the LED sub-pixel 204 is controlled by changing the gate-to-source voltage of the transistor M1. The gate-to-source voltage of the transistor M1 is set by the DAC 215 (when transistor M2 is turned on). The DAC 215 receives input digital codes from the processing circuit 224 and outputs analog voltages for setting the gate-to-source voltage of the transistor M1. The DAC 215 is configured to control intensity of emitted light from the first LED sub-pixel in response to the input digital code. The DAC 215 generates a voltage in response to the input digital code that controls a current through the LED.

In an ideal case, Rs is zero and R is infinite (the current through R is zero). In the ideal case, the gate-to-source voltage of the transistor M1 can be expressed as:

V_{GS}=Vₜₕ−\sqrt{Acⁿ} Eq. 1,

where V_{GS} is the gate-to-source voltage of the transistor M1, Vₜₕ is the threshold voltage of the transistor M1, c is the digital code input to the DAC 310 (in integer form), n is a real number representing gamma, and A is a real number and property of the LED sub-pixel 204. The values of Vₜₕ and A can differ across different LED sub-pixels 204 in the display.

If the DAC 215 is programmed for a specific voltage out as a function of digital code c, then there exists a relationship between the digital codes of two differing sub-pixels (due to factors such as differing Vₜₕ, A, etc.) that make their luminosity equal:

Vₜₕ¹−\sqrt{A¹cⁿ¹}=Vₜₕ²−\sqrt{A²cⁿ²} Eq. 2,

where the superscripts 1 and 2 represent a first and a second LED sub-pixel, respectively. To simplify the calculations, it can be assumed that the threshold voltages of the two subpixels are equal to each other. In order to compensate for the differences in A¹ and A², the digital code for one of the sub-pixels can be scaled by a factor m:

\sqrt{A¹cⁿ¹}=\sqrt{A²(mc)ⁿ²} Eq. 3.

After setting the threshold voltages to be equal, solving for m results in:

$$m = {( \frac{{A}^{1}}{{A}^{2}} {c}^{n 1 - n 2} )}^{1 / n 2} , \qquad Eq . 4.$$

If the gamma of the two subpixels are the same, as is typically the case if the subpixels are in close proximity, then the above equation reduces to a constant value for the scaling factor m. In other words, in order to keep the brightness of the two subpixels the same, the second sub-pixel should be addressed with the code c scaled by m, whereas the first sub-pixel should be addressed at c with a scale factor of 1. In equation form:

Cₒᵤₜ=mCᵢₙ, Eq. 5.

As shown in Equation 4, m is a constant for the ideal LED sub-pixel. However, in practice, the LED sub-pixel is not ideal. Thus, Rs is not zero and R is not infinite. In the non-ideal case, Equation 1 becomes:

V_{GS}=Vₜₕ−\sqrt{Acⁿ+B ln(1+Dcⁿ)} Eq. 6,

where B and D are real number properties of the LED sub-pixel 204. Equation 2 becomes:

Vₜₕ¹−\sqrt{A¹cⁿ+B¹ ln(1+D¹cⁿ)}=Vₜₕ²−\sqrt{A²cⁿ+B² ln(1+D²cⁿ)} Eq. 7.

Finally, setting the threshold voltages and the gammas to be equal (for simplicity, as before) results in:

\sqrt{A¹cⁿ+B¹ ln(1+D¹cⁿ)}={square root over (A²(mc)ⁿ+B² ln(1+D²(mc)ⁿ))} Eq. 8.

Equation 8 cannot be satisfied using a constant value of m for arbitrary values of A, B, and D. In order to make the equality in Equation 8 hold, m has to be a function of digital code c.

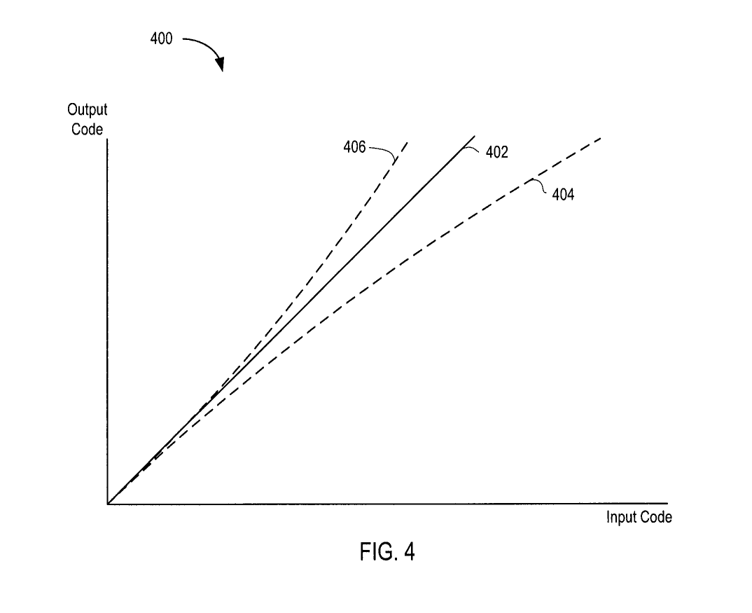

FIG. 4 is a graph 400 depicting input code versus output code for an LED sub-pixel. In the graph 400, the x-axis represents the input code and the y-axis represents the output code. In the ideal case (Rs=0; R=infinity), cₒᵤₜ=m*cᵢₙ, where m is a constant. This is illustrated by curve 402 in the graph 400. The non-ideal case (Rs≠0; R≠finite), f(cᵢₙ) can be approximated by cₒᵤₜ=xcᵢₙ^{y}, where x and y are real numbers. Curve 404 shows the case where y<1 and curve 406 shows the case where y>1. Thus, in the non-ideal case, the relationship between input code and output code is nonlinear and a constant scaling factor cannot be used. From Equation 8, the scaling factor m varies as a function of digital code.

Returning to FIG. 2, the correction circuit 220 generates output digital codes from input digital codes using a non-linear function. The parameter generator circuit 214 supplies the constant parameters for the non-linear function for each LED sub-pixel. The memory 216 stores a set of values for each LED sub-pixel that are used to generate the constant parameters. In an embodiment, the correction circuit 220 implements the function cₒᵤₜ=x*cᵢₙ^{y}, where x and y are the constant parameters. The memory 216 can store a pair of values x and y for each of the LED sub-pixels. In another embodiment, the correction circuit 220 implements an second order or higher polynomial function. While a polynomial function is an approximation of the relationship between input and output code, the complexity of the correction circuit 220 can be reduced. The constant parameters are coefficients of the polynomial function. For example, the correction circuit 220 can implement cₒᵤₜ=m₀c+m₁c², where m₀ and m₁ are constant coefficients. The memory 216 stores a pair of values m₀ and m₁ for each of the LED sub-pixels. In general, the correction circuit 220 can implement cₒᵤₜ=m(c)*c, where m(c)=m₀+m₁*c+m₂*c²+ . . . +mₙ₋₁*cⁿ⁻¹ and n is the order of the polynomial function implemented by the correction circuit 220. Hence, the scaling factor m becomes a function of count, rather than a constant value. The memory 216 stores a set of values for each LED sub-pixel, rather than a single constant scaling factor. The set of values are constant parameters of the scaling parameter, which is a function of code. Implementing a scaling factor as a function of code compensates for non-uniformities in the display panel with better accuracy in the practical case where shorting parasitic resistances are present.

In an embodiment, the correction circuit 220 implements a second order polynomial and the memory 216 stores a pair of values to be used as parameters of the polynomial for each LED sub-pixel. There is a tradeoff between accuracy, the complexity of the correction circuit 220, and the number of parameters needed for each LED sub-pixel. A second order polynomial can provide sufficient accuracy with the need of generating and storing only two values for each LED. In other embodiments, higher order polynomials can be used, which would require generation and storage of more than two parameters for each LED sub-pixel, as well as additional multipliers and adders in the correction circuit 220. The parameters for each LED sub-pixel can be generated during manufacture of the display by externally measuring the luminosity of each LED sub-pixel as a function of grey level. The luminosity of each LED sub-pixel for various grey levels can be compared with a reference LED sub-pixel to generate the values for m in Equation 8. A non-linear function is then fit to the determined values of m and the constant parameters of the non-linear function are stored in the memory 216 for each LED sub-pixel.

In an embodiment, the memory 216 also stores a code offset for each LED sub-pixel and the correction circuit 220 applies the offset for each LED sub-pixel. The offset is used to compensate for differences in threshold voltage of the driving transistor across different LED sub-pixels. The offsets for each LED sub-pixel can be stored in the memory 216 and updated over time.

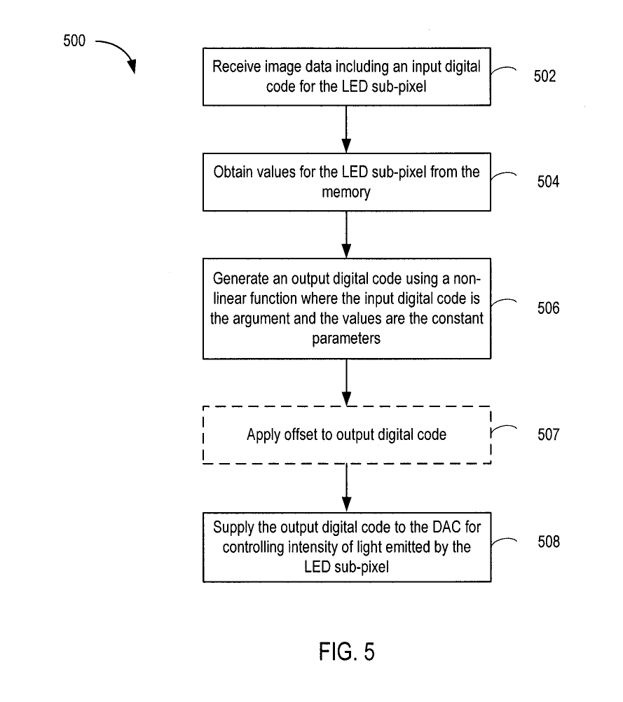

FIG. 5 is a flow diagram depicting a method 500 of driving an LED sub-pixel of a display according to an embodiment. The method 500 can be performed for each LED sub-pixel of the display. The method 500 begins at step 502, where the processing system 110 receives image data including an input digital code for the LED sub-pixel. At step 504, the processing system 110 obtains values for the LED sub-pixel from the memory 216. If the memory 216 stores compressed data, the processing system 110 decompresses the compressed data to obtain the values for the LED sub-pixels. For example, the memory 216 can output the values to the parameter generator circuit 214, which generates parameters for use by the correction circuit 220. At step 506, the correction circuit 220 generates an output digital code using a non-linear function where the input digital code is the argument and the values are the constant parameters. In an embodiment, the non-linear function is a second or higher-order polynomial function and the values are coefficients. At step 508, the processing circuit 224 supplies the output digital code to the DAC for controlling intensity of light emitted by the LED sub-pixel. In an embodiment, at step 507, the correction circuit 220 applies an offset to the output digital code.

The embodiments and examples set forth herein were presented in order to best explain the embodiments in accordance with the present technology and its particular application and to thereby enable those skilled in the art to make and use the disclosure. However, those skilled in the art will recognize that the foregoing description and examples have been presented for the purposes of illustration and example only. The description as set forth is not intended to be exhaustive or to limit the disclosure to the precise form disclosed.

In view of the foregoing, the scope of the present disclosure is determined by the claims that follow.

We claim:

1. A processing system for driving a display having light-emitting diode (LED) sub-pixels, the processing system comprising:
a memory configured to store a first plurality of values for a first LED sub-pixel of the LED sub-pixels;
a processing circuit, coupled to the memory, configured to:
receive image data for the display, the image data comprising a first input digital code for the first LED sub-pixel;
set an argument of a non-linear function to the first input digital code;
set a plurality of constant parameters of the non-linear function to the plurality of values; and
generate a first output digital code using the non-linear function; and
a display driver comprising a first digital-to-analog converter (DAC) configured to control intensity of emitted light from the first LED sub-pixel in response to the first output digital code.

2. The processing system of claim 1, wherein the display comprises:
a transistor coupled to an LED of the first LED sub-pixel, the transistor having a gate coupled to the first DAC; and
wherein the first DAC is configured to generate a voltage in response to the first output digital code that controls a current through the LED.

3. The processing system of claim 1, wherein the non-linear function is a second or higher order polynomial function and the plurality of constant parameters are coefficients, and wherein the first plurality of values for the first LED sub-pixel are values for the coefficients.

4. The processing system of claim 3, wherein the non-linear function is a second order polynomial function in the form of m₀c+m₁c², where c is the argument and m₀ and m₁ are the plurality of constant parameters, and wherein the first plurality of values for the first LED sub-pixel are a pair of values for m₀ and m₁.

5. The processing system of claim 1, wherein the processing circuit is configured to generate the first output digital code by adding an offset to a result of computing the non-linear function given the first input digital code and the first plurality of values.

6. The processing system of claim 1, wherein the memory is configured to:
store a second plurality of values for a second LED sub-pixel of the LED sub-pixels, wherein the image data comprises a second input digital code for the second LED sub-pixel;
wherein the processing circuit is further configured to generate a second output digital code using the non-linear function by setting the argument to the second input digital code and setting the plurality of constant parameters to the second plurality of values; and
wherein the display driver comprises a second DAC configured to control intensity of emitted light from the second LED sub-pixel in response to the second output digital code.

7. The processing system of claim 1, wherein the non-linear function is in the form of xc^{y}, where c is the argument and x and y are the plurality of constant parameters, and wherein the first plurality of values for the first LED sub-pixel are a pair of values for x and y.

8. An input device, comprising:
a display having light-emitting diode (LED) sub-pixels; and
a processing system, coupled to the display, comprising:
a memory configured to store a first plurality of values for a first LED sub-pixel of the LED sub-pixels;
a processing circuit, coupled to the memory, configured to:
receive image data for the display, the image data comprising a first input digital code for the first LED sub-pixel;
set an argument of a non-linear function to the first input digital code;
set a plurality of constant parameters of the non-linear function to the plurality of values; and
generate a first output digital code using the non-linear function; and
a display driver, coupled to the display and the processing circuit, comprising a first digital-to-analog converter (DAC), the first DAC configured to control intensity of emitted light from the first LED sub-pixel in response to the first output digital code.

9. The input device of claim 8, wherein the display comprises:
a transistor coupled to an LED of the first LED sub-pixel, the transistor having a gate coupled to the first DAC; and
wherein the first DAC is configured to generate a voltage in response to the first output digital code that controls a current through the LED.

10. The input device of claim 8, wherein the non-linear function is a second or higher order polynomial function and the plurality of constant parameters are coefficients, and wherein the first plurality of values for the first LED sub-pixel are values for the coefficients.

11. The input device of claim 10, wherein the non-linear function is a second order polynomial function in the form of m₀c+m₁c², where c is the argument and m₀ and m₁ are the plurality of constant parameters, and wherein the first plurality of values for the first LED sub-pixel are a pair of values for m₀ and m₁.

12. The input device of claim 8, wherein the processing circuit is configured to generate the first output digital code by adding an offset to a result of computing the non-linear function given the first input digital code and the first plurality of values.

13. The input device of claim 8, wherein the memory is configured:
to store a second plurality of values for a second LED sub-pixel of the LED sub-pixels, wherein the image data comprises a second input digital code for the second LED sub-pixel;
wherein the processing circuit is further configured to generate a second output digital code using the non-linear function by setting the argument to the second input digital code and setting the plurality of constant parameters to the second plurality of values; and
wherein the display driver comprises a second DAC configured to control intensity of emitted light from the second LED sub-pixel in response to the second output digital code.

14. The input device of claim 8, wherein the non-linear function is in the form of xc^{y}, where c is the argument and x and y are the plurality of constant parameters, and wherein the first plurality of values for the first LED sub-pixel are a pair of values for x and y.

15. A method of driving a display, the display comprising light-emitting diode (LED) sub-pixels, the method comprising:
receiving image data for the display, the image data comprising a first input digital code for a first LED sub-pixel of the LED sub-pixels;
obtaining a first plurality of values for the first LED sub-pixel from a memory;
generating, using a processing circuit coupled to the memory, a first output digital code using a non-linear function having an argument and a plurality of constant parameters, where the processing circuit is configured to set the argument to the first input digital code and set the plurality of constant parameters to the plurality of values; and
supplying the first output digital code to a first digital-to-analog converter (DAC) configured to control intensity of emitted light from the first LED sub-pixel in response to the first output digital code.

16. The method of claim 15 further comprising:
generating a voltage in response to the first output digital code that controls a current to an LED of the first LED sub-pixel.

17. The method of claim 15, wherein the non-linear function is a second or higher order polynomial function and the plurality of constant parameters are coefficients, and wherein the first plurality of values for the first LED sub-pixel are values for the coefficients.

18. The method of claim 17, wherein the non-linear function is a second order polynomial function in the form of m₀c+m₁c², where c is the argument and m₀ and m₁ are the plurality of constant parameters, and wherein the first plurality of values for the first LED sub-pixel are a pair of values for m₀ and m₁.

19. The method of claim 15, wherein generating the first output digital code comprises:
adding an offset to a result of computing the non-linear function given the first input digital code and the first plurality of values.

20. The method of claim 15, wherein the non-linear function is in the form of xc^{y}, where c is the argument and x and y are the plurality of constant parameters, and wherein the first plurality of values for the first LED sub-pixel are a pair of values for x and y.
